(19) United States
(12) Patent Application Publication
(10) Pub. No.: US 2009/0206405 A1
(43) Pub. Date: Aug. 20, 2009

(54) FIN FIELD EFFECT TRANSISTOR STRUCTURES HAVING TWO DIELECTRIC THICKNESSES

(76) Inventors: Brian S. Doyle, Portland, OR (US); Ravi Pillarisetty, Portland, OR (US); Robert S. Chau, Beaverton, OR (US)

Correspondence Address: COOL PATENT, P.C.;c/o CPA Global, P.O. BOX 52050, MINNEAPOLIS, MN, 55402, US

(21) Appl. No.: 12/032,594

(22) Filed: Feb. 15, 2008

(51) Int. Cl. H01L 21/336; H01L 29/78

(52) U.S. Cl. 257/365; 438/283; 257/E21.421; 257/E29.264

(57) ABSTRACT

Fin field-effect-transistor (finFET) structures having two dielectric thicknesses are generally described. In one example, an apparatus includes a semiconductor substrate, a semiconductor fin coupled with the semiconductor substrate, the semiconductor fin having at least a first surface, a second surface, and a third surface, the third surface being substantially parallel to the first surface and substantially perpendicular to the second surface, a spacer dielectric coupled to the second surface of the semiconductor fin, a back gate dielectric having a back gate dielectric thickness coupled to the first surface of the semiconductor fin, and a front gate dielectric having a front gate dielectric thickness coupled to the third surface of the semiconductor fin wherein the back gate dielectric thickness is greater than the front gate dielectric thickness

### BACKGROUND

Generally, fin field-effect-transistor (finFET) structures such as floating body cell (FBC) devices are emerging for incorporation in multi-gate logic architectures such as tri-gate logic, for example.

### BRIEF DESCRIPTION OF THE DRAWINGS

Embodiments disclosed herein are illustrated by way of example, and not by way of limitation, in the figures of the accompanying drawings in which like reference numerals refer to similar elements and in which:

FIGS. 1a-n depict a process schematic for fabricating a finFET structure having two dielectric thicknesses, according to but one embodiment;

FIG. 2 is a flow diagram of a method for fabricating a finFET structure having two dielectric thicknesses, according to but one embodiment; and

FIG. 3 is a diagram of an example system in which embodiments of the present invention may be used, according to but one embodiment.

It will be appreciated that for simplicity and/or clarity of illustration, elements illustrated in the figures have not necessarily been drawn to scale. For example, the dimensions of some of the elements may be exaggerated relative to other elements for clarity. Further, if considered appropriate, reference numerals have been repeated among the figures to indicate corresponding and/or analogous elements.

### DETAILED DESCRIPTION

Embodiments of finFET structures having two dielectric thicknesses are described herein. In the following description, numerous specific details are set forth to provide a thorough understanding of embodiments disclosed herein. One skilled in the relevant art will recognize, however, that the embodiments disclosed herein can be practiced without one or more of the specific details, or with other methods, components, materials, and so forth. In other instances, well-known structures, materials, or operations are not shown or described in detail to avoid obscuring aspects of the specification.

Reference throughout this specification to “one embodiment” or “an embodiment” means that a particular feature, structure or characteristic described in connection with the embodiment is included in at least one embodiment. Thus, appearances of the phrases “in one embodiment” or “in an embodiment” in various places throughout this specification are not necessarily all referring to the same embodiment. Furthermore, the particular features, structures or characteristics may be combined in any suitable manner in one or more embodiments.

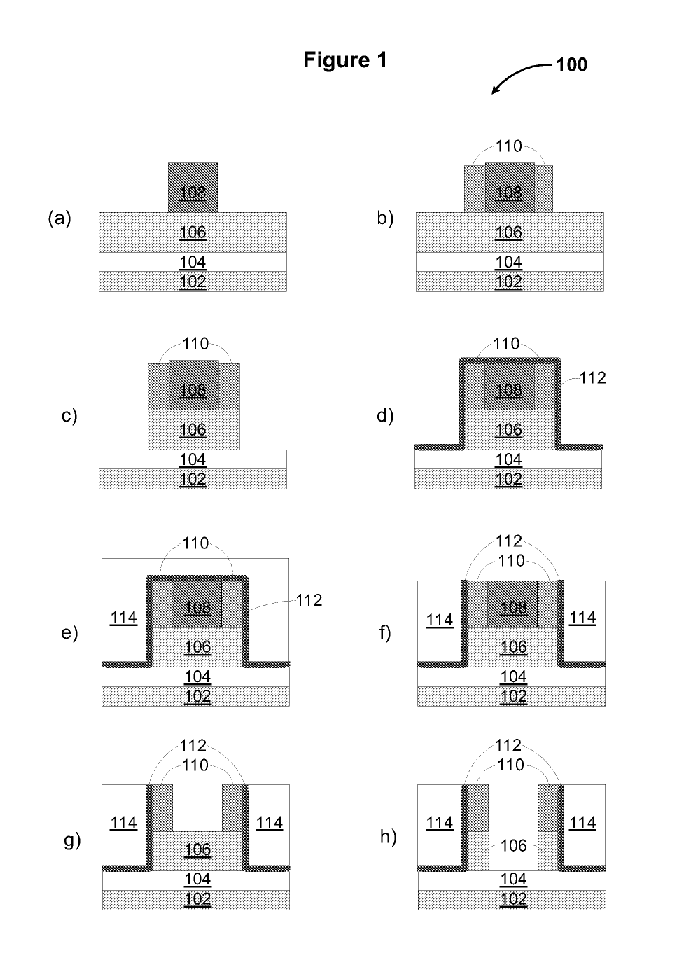

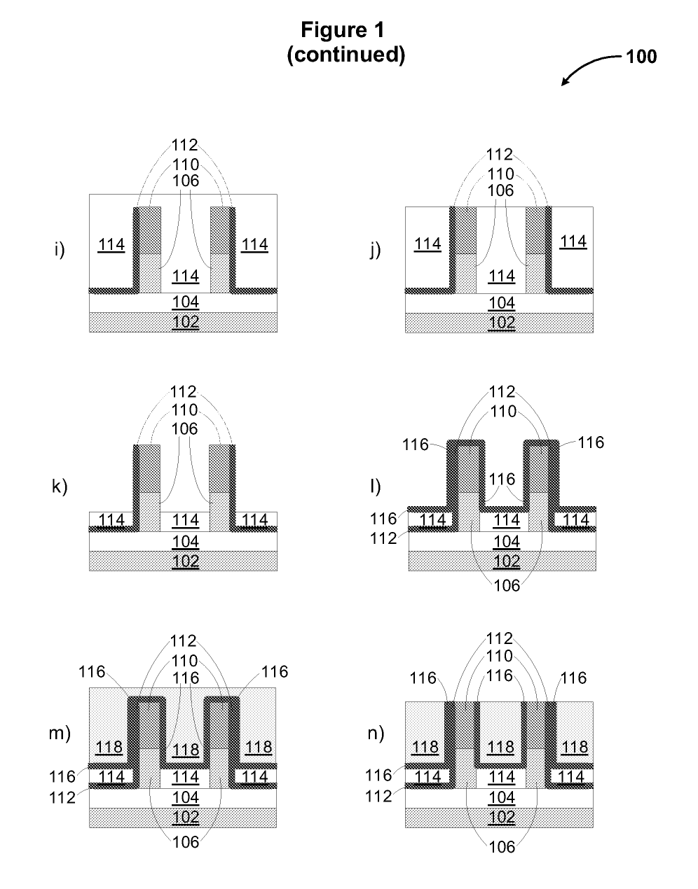

FIGS. 1a-n depict a process schematic for fabricating a finFET structure having two dielectric thicknesses, according to but one embodiment. FIGS. 1a-n include cross-section depictions according to one or more embodiments.

In an embodiment according to FIG. 1a, an apparatus 100 includes a semiconductor substrate 102, dielectric film 104, semiconductor material 106, and sacrificial pillar 108, each coupled as shown. A semiconductor substrate 102 may be a bulk substrate or silicon-on-insulator (SOI) substrate, in one or more embodiments. FIG. 1a may depict an SOI substrate 102, 104, 106 including a semiconductor substrate 102, an insulator 104, and a semiconductor material 106, each coupled as shown. SOI substrate 102, 104, 106 may be referred to as a semiconductor substrate 102, 104, 106. In a bulk silicon substrate embodiment, for example, the structures labeled 102, 104, and 106 may include a bulk semiconductor material. In an embodiment, the semiconductor substrate 102 and the semiconductor material 106 include silicon, the dielectric film 104 includes oxide, and the sacrificial pillar 108 includes silicon nitride.

In an embodiment, the sacrificial pillar 108 is formed by depositing silicon nitride to a semiconductor substrate 102, 104, 106 and etching the silicon nitride to form a sacrificial pillar 108 coupled to the semiconductor substrate 102, 104, 106. The sacrificial pillar 108 may have at least a first surface, a second surface, and a third surface, the first and third surfaces being substantially parallel to one another and being substantially perpendicular to the second surface and/or the surface of the semiconductor substrate. In one embodiment, the first and third surfaces of the sacrificial pillar 108 are referred to as sidewalls and the second surface of the sacrificial pillar 108 is referred to as the top surface for clarity of discussion, although no particular orientation is necessarily required.

In an embodiment according to FIG. 1b, an apparatus 100 includes a semiconductor substrate 102, dielectric film 104, semiconductor material 106, sacrificial pillar 108, and spacer dielectric 110, each coupled as shown. In an embodiment, FIG. 1b is a depiction of FIG. 1a after deposition and patterning of a spacer dielectric 110. Patterning may include lithography spin, expose, and develop steps and/or etching to define structures. In an embodiment, the spacer dielectric 110 is coupled to the first and third surfaces of the sacrificial pillar 108. The spacer dielectric 110 may also be coupled to the semiconductor material 106. In an embodiment, the spacer dielectric 110 includes carbon-doped silicon nitride.

In an embodiment according to FIG. 1c, an apparatus 100 includes a semiconductor substrate 102, dielectric film 104, intermediate semiconductor fin structure 106, sacrificial pillar 108, and spacer dielectric 110, each coupled as shown. FIG. 1c may be a depiction of FIG. 1b after a deep fin etch is performed to remove semiconductor material 106 to form an intermediate semiconductor fin structure 106. The etched sidewalls of the intermediate semiconductor fin structure 106 may form one or more surfaces of a back gate. In an embodiment, etching the semiconductor material 106 removes semiconductor material that is not masked or protected by the sacrificial pillar 108 and the spacer dielectric 110 to form one or more first surfaces of a semiconductor fin (depicted in FIGS. 1h-1n). In an embodiment, the first surfaces of the intermediate semiconductor fin structure 106 are substantially parallel to the first and third surfaces of the sacrificial pillar 108 and are exposed for deposition of a gate dielectric. In another embodiment, the first surfaces of the intermediate semiconductor fin structure 106 are substantially coplanar to surfaces of the spacer dielectric 110, as suggested in FIG. 1c.

In an embodiment according FIG. 1d, an apparatus 100 includes a semiconductor substrate 102, dielectric film 104, intermediate semiconductor fin structure 106, sacrificial pillar 108, spacer dielectric 110, and a first gate dielectric 112 having a first thickness, T1, each coupled as shown. FIG. 1d may be a depiction of FIG. 1c after a first gate dielectric 112 has been deposited to at least the first surfaces or back gate structures of the intermediate semiconductor fin structure 106. In other embodiments, the first gate dielectric 112 is deposited to the structures 104, 106, 108, 110 as depicted. The first gate dielectric 112 may include high-k gate dielectrics such as gate oxides including hafnium oxide, zirconium oxide, or combinations thereof, for example. Other suitable gate dielectric 112 materials may be used in other embodiments. A first gate dielectric 112 may be deposited using atomic layer deposition (ALD), chemical vapor deposition (CVD), physical vapor deposition (PVD), or any suitable deposition method.

In an embodiment according to FIGS. 1e-f, an apparatus 100 includes a semiconductor substrate 102, dielectric film 104, intermediate semiconductor fin structure 106, sacrificial pillar 108, spacer dielectric 110, a first gate dielectric 112 having a first thickness, T1, and an isolation dielectric 114, each coupled as shown. FIG. 1e may be a depiction of FIG. 1d after isolation dielectric 114 has been deposited to fill trenches as shown. In an embodiment according to FIG. 1e, isolation dielectric 114 material is deposited to the first gate dielectric 112 having a first thickness (T1). FIG. 1f may be a depiction of FIG. 1e after isolation dielectric 114 has been polished. In an embodiment according to FIG. 1f, isolation dielectric 114 material is polished to expose the second or top surface of the sacrificial pillar 108. Polishing may expose the spacer dielectric 110 as well.

In an embodiment according to FIG. 1g, an apparatus 100 includes a semiconductor substrate 102, dielectric film 104, intermediate semiconductor fin structure 106, spacer dielectric 110, a first gate dielectric 112 having a first thickness, T1, and an isolation dielectric 114, each coupled as shown. FIG. 1g may be a depiction of FIG. 1f after the sacrificial pillar 108 has been selectively removed. In an embodiment, the sacrificial pillar 108 is etched to completely or substantially remove the sacrificial pillar 108. In an embodiment, a wet etch process including hot phosphorous is used to remove a sacrificial pillar 108 including silicon nitride where the spacer dielectric 110 includes carbon-doped silicon nitride to withstand the hot phosphorous etch.

In an embodiment according to FIG. 1h, an apparatus 100 includes a semiconductor substrate 102, dielectric film 104, semiconductor fin structures 106, spacer dielectric 110, a first gate dielectric 112 having a first thickness, T1, and an isolation dielectric 114, each coupled as shown. FIG. 1h may be a depiction of FIG. 1g after a trench etch has been performed to form a front gate structure or third surface of semiconductor fins 106. In an embodiment, the semiconductor substrate 106 or intermediate semiconductor fin structure is etched in the region where the sacrificial pillar has been removed using the spacer dielectric 110 as an etch mask to prevent underlying material 106 from being removed. In an embodiment, etching the semiconductor substrate 106 forms one or more third surfaces of a semiconductor fin 106 where the third surfaces are substantially parallel to the first surfaces of the semiconductor fin 106 and substantially perpendicular to second surfaces of the semiconductor fin 106.

The first and third surfaces of the semiconductor fin 106 may be sidewalls in the orientation embodiment depicted in FIGS. 1a-n, and the second surface of the semiconductor fin 106 may be the top surface. In an embodiment according to FIG. 1h, the first surfaces of semiconductor fins 106 are coupled to the first gate dielectric 112, the second surfaces of the semiconductor fins 106 are coupled to the spacer dielectric 110, and the third surfaces of the semiconductor fins 106 remain exposed. In another embodiment, a first surface of the semiconductor fin 106 includes or is part of a back gate of a dual-gate structure and the third surface of the semiconductor fin 106 includes or is part of a front gate of a dual-gate structure.

In an embodiment according to FIG. 1i, an apparatus 100 includes a semiconductor substrate 102, dielectric film 104, semiconductor fin structures 106, spacer dielectric 110, a first gate dielectric 112 having a first thickness, T1, and an isolation dielectric 114, each coupled as shown. FIG. 1i may be a depiction of FIG. 1h after isolation dielectric 114 has been deposited. In an embodiment, blanket isolation dielectric 114 material is deposited to the first gate dielectric 112 having the first thickness, the spacer dielectric 110, and the third surface of the semiconductor fin 106. Such deposition 114 may occur after forming a third surface of the semiconductor fin 106 and prior to depositing a second gate dielectric 116 having a second thickness. FIG. 1j may be a depiction of FIG. 1i after the isolation dielectric 114 has been polished back to the spacer dielectric 110.

In an embodiment according to FIG. 1k, an apparatus 100 includes a semiconductor substrate 102, dielectric film 104, semiconductor fin structures 106, spacer dielectric 110, a first gate dielectric 112 having a first thickness, T1, and an isolation dielectric 114, each coupled as shown. FIG. 1k may be a depiction of FIG. 1j after the isolation dielectric 114 has been recessed to a selected thickness. In an embodiment, the isolation dielectric 114 is recessed using an etch process such that the third surface of the semiconductor fin 106 is at least partially exposed and a portion of the first gate dielectric 112 coupled directly to the first surface of the semiconductor fin 106 is partially exposed. Exposed structures may be deposited with a second gate dielectric 116 in FIG. 11.

In an embodiment according to FIG. 1l, an apparatus 100 includes a semiconductor substrate 102, dielectric film 104, semiconductor fin structures 106, spacer dielectric 110, a first gate dielectric 112 having a first thickness, T1, an isolation dielectric 114, and a second gate dielectric 116 having a second thickness, T2, each coupled as shown. FIG. 11 may be a depiction of FIG. 1k after a second gate dielectric 116 having a second thickness (T2) has been deposited to exposed surfaces of FIG. 1k. In an embodiment, deposition of a second gate dielectric 116 having a second thickness, T2, to the first surface and to the third surface of the semiconductor fin structures 106 forms a first surface having a combined gate dielectric thickness of T1+T2 and a third surface having a gate dielectric thickness of T2.

Semiconductor fin 106 may be a dual-gate structure of a finFET floating body cell device wherein the first surface of the semiconductor fin 106 includes a back gate of the dual-gate structure and wherein the third surface of the semiconductor fin 106 includes a front gate of the dual-gate structure. In an embodiment, the first gate dielectric 112 has a first thickness, T1, that is sufficiently thick to support short channel effects of a dual-gate finFET architecture, or to receive an electrical signal for transistor switching, or combinations thereof. In an embodiment, the second gate dielectric 116 has a second thickness, T2, wherein the second thickness, T2, in combination with the first thickness, T1, is sufficiently thick to store charge, prevent leakage, or combinations thereof. In one example embodiment, a first surface of semiconductor fin 106 has combined thickness (T1+T2) of about 20-50 angstroms and a third surface of semiconductor fin 106 has a thickness (T2) of about 10-30 angstroms. Such thicknesses are merely examples and other thicknesses may be suitable according to device design, scaling, and integration.

In an embodiment, deposition of the second gate dielectric 116 forms a floating body cell finFET structure having two dielectric thicknesses, T1 and T1+T2. Such deposition of the second gate dielectric 116 may be targeted such that a back gate of a floating body cell is thick enough to eliminate leakage while the front gate maintains a thin enough gate dielectric to support or reduce short channel effects of a double-gate finFET architecture. Two gate dielectric thicknesses may allow incorporation of FinFET floating body cells in a multi-gate logic architecture such as tri-gate logic architecture, for example.

In an embodiment according to FIG. 1m, an apparatus 100 includes a semiconductor substrate 102, dielectric film 104, semiconductor fin structures 106, spacer dielectric 110, a first gate dielectric 112 having a first thickness, T1, an isolation dielectric 114, a second gate dielectric 116 having a second thickness, T2, and a gate electrode 118, each coupled as shown. FIG. 1m may be a depiction of FIG. 1l after deposition of a gate electrode 118. In an embodiment, deposition of a gate electrode 118 includes deposition of gate electrode 118 to the gate dielectric material 112, 116 that is coupled to the first and third surfaces of the semiconductor fin 106. A gate electrode 118 may include polysilicon or any other suitable gate electrode material in one or more embodiments. FIG. 1n may be a depiction of FIG. 1m after polishing the gate electrode 118 back to the spacer dielectric 110 for further processing.

In an embodiment, an apparatus 100 includes a semiconductor substrate 102, a semiconductor fin 106 coupled with the semiconductor substrate 102, the semiconductor fin 106 having at least a first surface, a second surface, and a third surface, the third surface being substantially parallel to the first surface and substantially perpendicular to the second surface. For example, in the orientation depicted in FIG. 1n, the first and third surfaces of semiconductor fin 106 may be the sidewalls and the second surface may be the top surface of semiconductor fin 106. An apparatus 100 may further include a spacer dielectric 110 coupled to the second surface of the semiconductor fin 106, a back gate dielectric 112, 116 having a back gate dielectric thickness (T1+T2) coupled to the first surface of the semiconductor fin 106, and a front gate dielectric 116 having a front gate dielectric thickness (T2) coupled to the third surface of the semiconductor fin 106 wherein the back gate dielectric thickness is greater than the front gate dielectric thickness.

The semiconductor fin 106 may be a dual-gate structure of a finFET floating body cell device where the first surface of the semiconductor fin 106 is a back gate structure of the dual-gate structure and where the third surface of the semiconductor fin 106 is a front gate structure of the dual-gate structure. In an embodiment, the back gate dielectric 112, 116 includes a high-k gate oxide of sufficient thickness to store charge, prevent leakage, or combinations thereof. In another embodiment, the front gate dielectric 116 includes a high-k gate oxide of sufficient thickness to support short channel effects of a dual-gate finFET architecture, or to receive an electrical signal for transistor switching, or combinations thereof. In an embodiment, the back gate dielectric 112, 116 has a back gate dielectric thickness of about 20 to 50 angstroms and the front gate dielectric 116 has a front gate dielectric thickness of about 10 to 30 angstroms.

A gate electrode 118 may be coupled to the front 116 and back 112, 116 gate dielectrics. In an embodiment, a gate electrode 118 includes polysilicon, a semiconductor fin 106 includes silicon, a spacer gate dielectric 110 includes carbon-doped silicon nitride, and a semiconductor substrate 102 includes silicon. Other suitable materials may be used for structures of apparatus 1100 in other embodiments and are not necessarily limited to the example materials set forth above. In an embodiment, a semiconductor substrate includes bulk substrate, silicon-on-insulator (SOI) substrate, or combinations thereof.

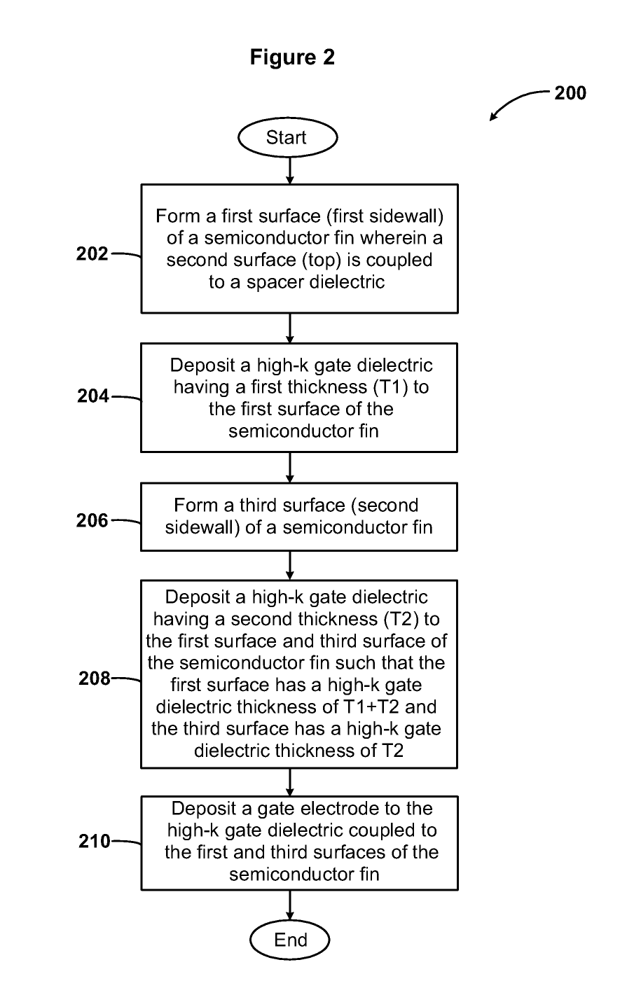

FIG. 2 is a flow diagram of a method for fabricating a finFET structure having two dielectric thicknesses, according to but one embodiment. In an embodiment, a method 200 includes forming a first surface of a semiconductor fin wherein a second surface is coupled to a spacer dielectric 202, depositing a high-k gate dielectric having a first thickness (T1) to the first surface of the semiconductor fin 204, forming a third surface of a semiconductor fin 206, depositing a high-k gate dielectric having a second thickness (T2) to the first surface and third surface of the semiconductor fin 208 such that the first surface has a high-k gate dielectric thickness of T1+T2 and the third surface has a high-k gate dielectric thickness of T2, and depositing a gate electrode to the high-k gate dielectric coupled to the first and third surfaces of the semiconductor fin 210. A first surface may be a first sidewall, a second surface may be a top surface, and a third surface may be a second sidewall according to one embodiment, although no particular orientation is necessarily required.

Method 200 may incorporate and/or accord with various embodiments already described with respect to FIGS. 1a-n. In an embodiment, a method 200 includes forming a first surface of a semiconductor fin 202, the first surface being substantially perpendicular to a second surface of the semiconductor fin, where the second surface is coupled to a spacer dielectric. Forming a first surface of a semiconductor fin 202 may include forming a sacrificial pillar coupled to a semiconductor substrate, the sacrificial pillar having at least a first surface, a second surface, and a third surface, the first and third surfaces of the sacrificial pillar being substantially parallel to one another and being substantially perpendicular to the second surface of the sacrificial pillar and the surface of the semiconductor substrate. Forming a sacrificial pillar may include depositing silicon nitride to a semiconductor substrate and etching the silicon nitride to form a sacrificial pillar, the pillar of silicon nitride being coupled to the semiconductor substrate.

Forming a first surface of a semiconductor fin 202 may further include forming a spacer dielectric, the spacer dielectric being coupled to the first and third surfaces of the sacrificial pillar and coupled to the semiconductor substrate and etching the semiconductor substrate to remove semiconductor substrate material that is not masked by the sacrificial pillar and the spacer dielectric to form the first surface of the semiconductor fin where the first surface of the semiconductor fin is substantially parallel to the first and third surfaces of the sacrificial pillar. Forming a spacer dielectric may include depositing a spacer dielectric material including carbon-doped silicon nitride to the semiconductor substrate and to the sacrificial pillar. The spacer dielectric material may be silicon-nitride doped with carbon subsequent to deposition.

A method 200 may include depositing a first gate dielectric having a first thickness, T1, to the first surface of the semiconductor fin 204. Depositing a first gate dielectric 204 may include depositing a high-k gate dielectric. Suitable methods for thin film deposition may include ALD, CVD, PVD, or any other suitable method. A first gate dielectric may have a first thickness, T1, in the range of about 10-30 angstroms, for example.

Forming a third surface of a semiconductor fin 206 may include depositing isolation dielectric material to the first gate dielectric having a first thickness (T1), polishing the isolation dielectric material to expose the second surface of the sacrificial pillar and the spacer dielectric, etching the sacrificial pillar to completely or substantially remove the sacrificial pillar, and etching the semiconductor substrate in the region where the sacrificial pillar is removed using the spacer dielectric as an etch mask to form the third surface of the semiconductor fin wherein the third surface of the semiconductor fin is substantially parallel to the first surface of the semiconductor fin.

A method 200 may further include depositing a blanket isolation dielectric material to the first gate dielectric having the first thickness, the spacer dielectric, and the third surface of the semiconductor fin after forming a third surface of the semiconductor fin 206 and prior to depositing a second gate dielectric having a second thickness 208. In an embodiment, method 200 includes recessing the blanket isolation dielectric material to a thickness such that the third surface of the semiconductor fin is at least partially exposed and a portion of the first gate dielectric coupled directly to the first surface of the semiconductor fin is partially exposed.

A method 200 may include depositing a second gate dielectric having a second thickness, T2, to the first surface and to the third surface of the semiconductor fin 208 such that the first surface has a gate dielectric thickness of T1+T2 and the third surface has a gate dielectric thickness of T2. Depositing a second gate dielectric 208 may include depositing a high-k gate dielectric, which may or may not be the same material used for the first gate dielectric. Suitable methods for thin film deposition may include ALD, CVD, PVD, or any other suitable method. A second gate dielectric may have a first thickness, T2, in the range of about 10-30 angstroms, for example. A combined first and second gate dielectric may have a thickness in the range of about 20-50 angstroms according to one example embodiment.

In an embodiment, depositing a second gate dielectric having a second thickness 208 includes depositing a high-k gate dielectric to form a dual-gate structure of a finFET floating body cell device where the first surface of the semiconductor fin includes a back gate of the dual-gate structure and where the third surface of the semiconductor fin includes a front gate of the dual-gate structure. Depositing a first gate dielectric having a first thickness 204 may include depositing a high-k gate dielectric wherein the first thickness, T1, is sufficiently thick to support or reduce short channel effects of a dual-gate finFET architecture, or to receive an electrical signal for transistor switching, or combinations thereof. Depositing a second gate dielectric having a second thickness 208 may include depositing a high-k gate dielectric where the second thickness, T2, in combination with the first thickness, T1, is sufficiently thick to store charge, prevent leakage, or combinations thereof.

Various operations may be described as multiple discrete operations in turn, in a manner that is most helpful in understanding the invention. However, the order of description should not be construed as to imply that these operations are necessarily order dependent. In particular, these operations need not be performed in the order of presentation. Operations described may be performed in a different order than the described embodiment. Various additional operations may be performed and/or described operations may be omitted in additional embodiments.

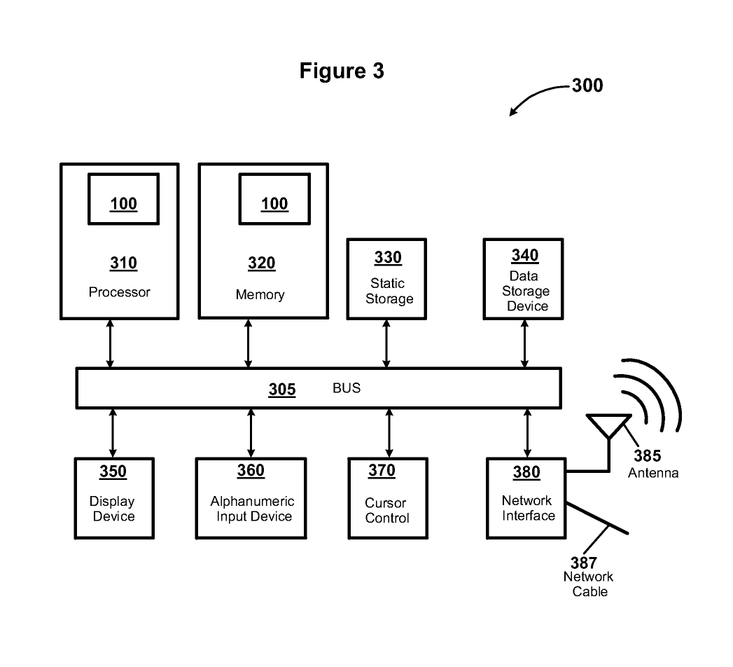

FIG. 3 is a diagram of an example system in which embodiments of the present invention may be used, according to but one embodiment. System 300 is intended to represent a range of electronic systems (either wired or wireless) including, for example, desktop computer systems, laptop computer systems, personal computers (PC), wireless telephones, personal digital assistants (PDA) including cellular-enabled PDAs, set top boxes, pocket PCs, tablet PCs, DVD players, or servers, but is not limited to these examples and may include other electronic systems. Alternative electronic systems may include more, fewer and/or different components.

In one embodiment, electronic system 300 includes an apparatus 100 having finFET structures with two dielectric thicknesses in accordance with embodiments described with respect to FIGS. 1-2. In an embodiment, an apparatus 100 having finFET structures with two dielectric thicknesses as described herein is part of an electronic system's processor 310 or memory 320.

Electronic system 300 may include bus 305 or other communication device to communicate information, and processor 310 coupled to bus 305 that may process information. While electronic system 300 may be illustrated with a single processor, system 300 may include multiple processors and/or co-processors. In an embodiment, processor 310 includes an apparatus 100 having finFET structures with two dielectric thicknesses in accordance with embodiments described herein. System 300 may also include random access memory (RAM) or other storage device 320 (may be referred to as memory), coupled to bus 305 and may store information and instructions that may be executed by processor 310.

Memory 320 may also be used to store temporary variables or other intermediate information during execution of instructions by processor 310. Memory 320 is a flash memory device in one embodiment. In another embodiment, memory 320 includes an apparatus 100 having finFET structures with two dielectric thicknesses as described herein.

System 300 may also include read only memory (ROM) and/or other static storage device 330 coupled to bus 305 that may store static information and instructions for processor 310. Data storage device 340 may be coupled to bus 305 to store information and instructions. Data storage device 340 such as a magnetic disk or optical disc and corresponding drive may be coupled with electronic system 300.

Electronic system 300 may also be coupled via bus 305 to display device 350, such as a cathode ray tube (CRT) or liquid crystal display (LCD), to display information to a user. Alphanumeric input device 360, including alphanumeric and other keys, may be coupled to bus 305 to communicate information and command selections to processor 310. Another type of user input device is cursor control 370, such as a mouse, a trackball, or cursor direction keys to communicate information and command selections to processor 310 and to control cursor movement on display 350.

Electronic system 300 further may include one or more network interfaces 380 to provide access to network, such as a local area network. Network interface 380 may include, for example, a wireless network interface having antenna 385, which may represent one or more antennae. Network interface 380 may also include, for example, a wired network interface to communicate with remote devices via network cable 387, which may be, for example, an Ethernet cable, a coaxial cable, a fiber optic cable, a serial cable, or a parallel cable.

In one embodiment, network interface 380 may provide access to a local area network, for example, by conforming to an Institute of Electrical and Electronics Engineers (IEEE) standard such as IEEE 802.11b and/or IEEE 802.11g standards, and/or the wireless network interface may provide access to a personal area network, for example, by conforming to Bluetooth standards. Other wireless network interfaces and/or protocols can also be supported.

IEEE 802.11b corresponds to IEEE Std. 802.11b-1999 entitled “Local and Metropolitan Area Networks, Part 11: Wireless LAN Medium Access Control (MAC) and Physical Layer (PHY) Specifications: Higher-Speed Physical Layer Extension in the 2.4 GHz Band,” approved Sep. 16, 1999 as well as related documents. IEEE 802.11g corresponds to IEEE Std. 802.11g-2003 entitled “Local and Metropolitan Area Networks, Part 11: Wireless LAN Medium Access Control (MAC) and Physical Layer (PHY) Specifications, Amendment 4: Further Higher Rate Extension in the 2.4 GHz Band,” approved Jun. 27, 2003 as well as related documents. Bluetooth protocols are described in “Specification of the Bluetooth System: Core, Version 1.1,” published Feb. 22, 2001 by the Bluetooth Special Interest Group, Inc. Previous or subsequent versions of the Bluetooth standard may also be supported.

In addition to, or instead of, communication via wireless LAN standards, network interface(s) 380 may provide wireless communications using, for example, Time Division, Multiple Access (TDMA) protocols, Global System for Mobile Communications (GSM) protocols, Code Division, Multiple Access (CDMA) protocols, and/or any other type of wireless communications protocol.

In an embodiment, a system 300 includes one or more omnidirectional antennae 385, which may refer to an antenna that is at least partially omnidirectional and/or substantially omnidirectional, and a processor 310 coupled to communicate via the antennae.

The above description of illustrated embodiments, including what is described in the Abstract, is not intended to be exhaustive or to limit to the precise forms disclosed. While specific embodiments and examples are described herein for illustrative purposes, various equivalent modifications are possible within the scope of this description, as those skilled in the relevant art will recognize.

These modifications can be made in light of the above detailed description. The terms used in the following claims should not be construed to limit the scope to the specific embodiments disclosed in the specification and the claims. Rather, the scope of the embodiments disclosed herein is to be determined by the following claims, which are to be construed in accordance with established doctrines of claim interpretation.

What is claimed is:

1. A method comprising:
forming a first surface of a semiconductor fin, the first surface being substantially perpendicular to a second surface of the semiconductor fin, wherein the second surface is coupled to a spacer dielectric;
depositing a first gate dielectric having a first thickness, T1, to the first surface of the semiconductor fin;
forming a third surface of the semiconductor fin, the third surface being substantially parallel to the first surface and substantially perpendicular to the second surface; and
depositing a second gate dielectric having a second thickness, T2, to the first surface and to the third surface of the semiconductor fin such that the first surface has a gate dielectric thickness of T1+T2 and the third surface has a gate dielectric thickness of T2.

2. A method according to claim 1 wherein depositing a second gate dielectric having a second thickness comprises depositing a high-k gate dielectric to form a dual-gate structure of a fin field-effect-transistor (finFET) floating body cell device wherein the first surface of the semiconductor fin comprises a back gate of the dual-gate structure and wherein the third surface of the semiconductor s fin comprises a front gate of the dual-gate structure.

3. A method according to claim 1 wherein depositing a first gate dielectric having a first thickness comprises depositing a high-k gate dielectric wherein the first thickness, T1, is sufficiently thick to support short channel effects of a dual-gate finFET architecture, or to receive an electrical signal for transistor switching, or combinations thereof, and wherein depositing a second gate dielectric having a second thickness comprises depositing a high-k gate dielectric wherein the second thickness, T2, in combination with the first thickness, T1, is sufficiently thick to store charge, prevent leakage, or combinations thereof.

4. A method according to claim 1 wherein forming a first surface of a semiconductor fin comprises:
forming a sacrificial pillar coupled to a semiconductor substrate, the sacrificial pillar having at least a first surface, a second surface, and a third surface, the first and third surfaces of the sacrificial pillar being substantially parallel to one another and being substantially perpendicular to the second surface of the sacrificial pillar and the surface of the semiconductor substrate;
forming a spacer dielectric, the spacer dielectric being coupled to the first and third surfaces of the sacrificial pillar and coupled to the semiconductor substrate; and
etching the semiconductor substrate to remove semiconductor substrate material that is not masked by the sacrificial pillar and the spacer dielectric to form the first surface of the semiconductor fin wherein the first surface of the semiconductor fin is substantially parallel to the first and third surfaces of the sacrificial pillar.

5. A method according to claim 4 wherein forming a sacrificial pillar comprises:
depositing silicon nitride to a semiconductor substrate; and
etching the silicon nitride to form a sacrificial pillar comprising silicon nitride coupled to the semiconductor substrate.

6. A method according to claim 4 wherein forming a spacer dielectric comprises:
depositing a spacer dielectric material comprising carbon-doped silicon nitride to the semiconductor substrate and to the sacrificial pillar; and
etching the spacer dielectric material to form a spacer dielectric.

7. A method according to claim 4 wherein forming a third surface of the semiconductor fin comprises:
depositing isolation dielectric material to the first gate dielectric having a first thickness (T1);
polishing the isolation dielectric material to expose the second surface of the sacrificial pillar and the spacer dielectric;
etching the sacrificial pillar to completely or substantially remove the sacrificial pillar; and
etching the semiconductor substrate in the region where the sacrificial pillar is removed using the spacer dielectric as an etch mask to form the third surface of the semiconductor fin wherein the third surface of the semiconductor fin is substantially parallel to the first surface of the semiconductor fin.

8. A method according to claim 1 further comprising:
depositing a blanket isolation dielectric material to the first gate dielectric having the first thickness, the spacer dielectric, and the third surface of the semiconductor fin after forming a third surface of the semiconductor fin and prior to depositing a second gate dielectric having a second thickness; and
recessing the blanket isolation dielectric material to a thickness such that the third surface of the semiconductor fin is at least partially exposed and a portion of the first gate dielectric coupled directly to the first surface of the semiconductor fin is partially exposed.

9. A method according to claim 1 further comprising:
depositing a gate electrode to the gate dielectric material that is coupled to the first and third surfaces of the semiconductor fin.

10. An apparatus comprising:
a semiconductor substrate;
a semiconductor fin coupled with the semiconductor substrate, the semiconductor fin having at least a first surface, a second surface, and a third surface, the third surface being substantially parallel to the first surface and substantially perpendicular to the second surface;
a spacer dielectric coupled to the second surface of the semiconductor fin;
a back gate dielectric having a back gate dielectric thickness coupled to the first surface of the semiconductor fin; and
a front gate dielectric having a front gate dielectric thickness coupled to the third surface of the semiconductor fin wherein the back gate dielectric thickness is greater than the front gate dielectric thickness.

11. An apparatus according to claim 10 wherein the semiconductor fin comprises a dual-gate structure of a fin field-effect-transistor (finFET) floating body cell device wherein the first surface of the semiconductor fin is a back gate structure of the dual-gate structure and wherein the third surface of the semiconductor fin is a front gate structure of the dual-gate structure.

12. An apparatus according to claim 10 wherein the back gate dielectric comprises a high-k gate oxide of sufficient thickness to store charge, prevent leakage, or combinations thereof, and wherein the front gate dielectric comprises a high-k gate oxide of sufficient thickness to support short channel effects of a dual-gate finFET architecture, or to receive an electrical signal for transistor switching, or combinations thereof.

13. An apparatus according to claim 10 wherein the semiconductor substrate comprises bulk substrate, silicon-on-insulator (SOI) substrate, or combinations thereof, the apparatus further comprising:
a gate electrode coupled to the front and back gate dielectrics.

14. An apparatus according to claim 13 wherein the semiconductor substrate comprises silicon, the semiconductor fin comprises silicon, the gate electrode comprises polysilicon, and the spacer gate dielectric comprises carbon-doped silicon nitride.

15. An apparatus according to claim 10 wherein the back gate dielectric has a back gate dielectric thickness of about 20 to 50 angstroms and wherein the front gate dielectric has a front gate dielectric thickness of about 10 to 30 angstroms.
